(19) United States
(12) Patent Application Publication
(10) Pub. No.: US 2025/0357911 A1
(43) Pub. Date: Nov. 20, 2025

(54) ZERO COUPLING BO REGION FOR BAW RESONATORS USING ANTIPARALLEL POLARIZATION PART

(71) Applicant: Qorvo US, Inc., Greensboro, NC (US)

(72) Inventors: Milad Zolfagharloo Koohi, Longwood, FL (US); Paul Stokes, Orlando, FL (US)

(21) Appl. No.: 19/207,731

(22) Filed: May 14, 2025

Related U.S. Application Data
(60) Provisional application No. 63/647,964, filed on May 15, 2024.

(51) Int. Cl. H03H 9/17; H03H 3/02; H03H 9/02

(52) U.S. Cl. CPC H03H 9/176; H03H 3/02; H03H 9/02031; H03H 9/175

(57) ABSTRACT

The present disclosure relates to a bulk acoustic wave (BAW) resonator, which includes a bottom electrode, a top electrode structure, and a ferroelectric layer vertically sandwiched in between. Herein, the ferroelectric layer, which is formed of a ferroelectric material having a box-shape polarization-electric field curve, includes a border portion and a central portion surrounded by the border portion. The border portion includes an antiparallel part having a first polarization and a parallel part having a second polarization in an opposite direction to the first polarization. The first polarization of the antiparallel part and the second polarization of the parallel part at least partially cancel each other out, such that an absolute value of a combined polarization of the border portion is smaller than an absolute value of a central polarization of the central portion. The central portion is configured to provide a resonance of the BAW resonator.

### RELATED APPLICATIONS

This application claims the benefit of provisional patent application Ser. No. 63/647,964, filed May 15, 2024, the disclosure of which is hereby incorporated herein by reference in its entirety.

### FIELD OF THE DISCLOSURE

The present disclosure relates to a bulk acoustic wave (BAW) resonator with effectively zero electromechanical coupling at a border region of the BAW resonator.

### BACKGROUND

Due to their small size, high Q values, and very low insertion losses at microwave frequencies, particularly those above 1.5 Gigahertz (GHz), bulk acoustic wave (BAW) filters have been widely used in many modern wireless applications. For instance, the BAW filters incorporating BAW resonators are the filter of choice for many 3^{rd} Generation (3G) and 4^{th} Generation (4G) wireless devices, and are destined to dominate filter applications for 5^{th} Generation (5G) wireless devices.

One example of a conventional BAW resonator 10 is illustrated in FIG. 1. The BAW resonator 10 includes a bottom electrode 12, a top electrode 14, and a piezoelectric layer 16 (which is sometimes referred to as a transduction layer) sandwiched between the bottom electrode 12 and the top electrode 14. Because of a finite lateral dimension of the BAW resonator 10, lateral wave spurious modes may be excited in the BAW resonator 10, which results in degradation of the quality factor (Q) of the BAW resonator 10. In this regard, a border (BO) ring 18 is included in the BAW resonator 10 to confine the energy inside the BAW resonator 10 and prevent the excitation of undesired lateral wave spurious modes. The BO ring 18 is over a top surface of the top electrode 14 around a periphery of the top electrode 14 within what is referred to herein as a BO region 20 of the BAW resonator 10.

Although the BO ring 18 effectively eliminates the lateral wave spurious modes, the BO ring 18 will cause an undesired BO spurious resonance mode near the main resonance of the device. The main cause for the excitation of the BO spurious resonance mode is a nonzero electromechanical coupling coefficient Kₑ² of the piezoelectric layer 16 within the BO region 20 (i.e., piezoelectric BO portions 16_BO). FIG. 2 shows a typical 1−|S₁₁|² response (1−|S₁₁|² is equal to the power ratio lost in a resonator) of the BAW resonator 10 with the BO ring 18. The frequency difference between the main resonance and the BO spurious resonance mode depends on thickness and width of the BO ring 18 and the frequency of the main resonance (e.g., less than 100 MHz). The undesired BO spurious resonance mode increases the transmission loss of filters that incorporate the BAW resonator 10.

Accordingly, there remains a need for improved BAW resonator designs to reduce or eliminate the BO spurious resonance mode in the BAW resonator, while retaining a high Q value and a low/no lateral wave spurious mode. Further, there is also a need to keep the final product cost effective.

### SUMMARY

The present disclosure relates to a bulk acoustic wave (BAW) resonator with effectively zero electromechanical coupling at a border region of the BAW resonator. The disclosed BAW resonator includes a bottom electrode, a top electrode structure, and a ferroelectric layer vertically sandwiched between the bottom electrode and the top electrode structure. Herein, the ferroelectric layer is formed of a ferroelectric material, which has a box-shape polarization-electric field (P-E) curve. The ferroelectric layer includes a ferroelectric border (BO) portion positioned at a periphery of the ferroelectric layer and a ferroelectric central portion surrounded by the ferroelectric BO portion. The ferroelectric BO portion includes an antiparallel part with a first polarization and a parallel part with a second polarization, which is in an opposite direction from the first polarization. The first polarization of the antiparallel part and the second polarization of the parallel part at least partially cancel each other out, such that an absolute value of a combined polarization of the ferroelectric BO portion is smaller than an absolute value of a central polarization of the ferroelectric central portion. The ferroelectric central portion is configured to provide a resonance of the BAW resonator.

In one embodiment of the BAW resonator, the first polarization of the antiparallel part is opposite to the central polarization of the ferroelectric central portion, while the second polarization of the parallel part is the same as the central polarization of the ferroelectric central portion.

In one embodiment of the BAW resonator, the first polarization of the antiparallel part and the second polarization of the parallel part substantially cancel each other out, such that the combined polarization of the ferroelectric BO portion is a zero polarization.

In one embodiment of the BAW resonator, the antiparallel part includes a number of antiparallel rings, while the parallel part includes a number of parallel rings alternating with the antiparallel rings in a horizontal plane. Each antiparallel ring has a closed ring shape in the horizontal plane, extends vertically through the ferroelectric BO portion, and has the first polarization. Each parallel ring has a closed ring shape in the horizontal plane, extends vertically through the ferroelectric BO portion, and has the second polarization.

In one embodiment of the BAW resonator, the antiparallel rings are not equally spaced. The antiparallel rings have a lower density adjacent to an interior side of the ferroelectric BO portion and a higher density adjacent to an outer edge of the ferroelectric BO portion, such that the combined polarization of the ferroelectric BO portion reduces from the interior side of the ferroelectric BO portion towards the outer edge of the ferroelectric BO portion.

In one embodiment of the BAW resonator, the antiparallel rings are equally spaced.

In one embodiment of the BAW resonator, the antiparallel part includes a number of antiparallel bars, and the parallel part includes a number of parallel bars alternating with the antiparallel bars in a horizontal plane. Each antiparallel bar extends through the ferroelectric BO portion in the horizontal plane and vertically through the ferroelectric BO portion, and has the first polarization. The antiparallel bars surround the ferroelectric central portion and are parallel to each other at each periphery side of the ferroelectric layer. Each parallel bar extends through the ferroelectric BO portion in the horizontal plane and vertically through the ferroelectric BO portion, and has the second polarization. The parallel bars surround the ferroelectric central portion and are parallel to each other at each periphery side of the ferroelectric layer.

In one embodiment of the BAW resonator, the antiparallel part includes a number of discrete antiparallel posts dispersed at the periphery of the ferroelectric layer and confined in the ferroelectric BO portion. The discrete antiparallel posts are separated from each other by the parallel part, and each discrete antiparallel post extends vertically through the ferroelectric BO portion and has the first polarization.

In one embodiment of the BAW resonator, the discrete antiparallel posts are equally spaced.

In one embodiment of the BAW resonator, the discrete antiparallel posts are unequally spaced.

In one embodiment of the BAW resonator, each discrete antiparallel post has a same shape and a same size in the horizontal plane.

In one embodiment of the BAW resonator, the discrete antiparallel posts have more than one shape in the horizontal plane.

In one embodiment of the BAW resonator, the discrete antiparallel posts have more than one size in the horizontal plane.

In one embodiment of the BAW resonator, the top electrode structure includes a top electrode base over the ferroelectric layer and a BO ring protruding from a periphery of the top electrode base. Herein, a region of the BAW resonator, within which the BO ring is located is a BO region. The ferroelectric BO portion is confined within the BO region and aligned underneath the BO ring, while the ferroelectric central portion is not covered by the BO ring.

In one embodiment of the BAW resonator, the top electrode structure has a flat shape.

In one embodiment of the BAW resonator, the ferroelectric material is scandium aluminum nitride (ScₓAl₁₋ₓN) and the P-E curve of ScₓAl₁₋ₓN is dependent on a scandium concentration x.

According to one embodiment, the BAW resonator further includes a bottom Brag reflector formed underneath the bottom electrode.

According to one embodiment, the BAW resonator further includes a top Brag reflector formed over the top electrode structure.

According to one embodiment, a method of implementing a BAW resonator starts with providing an initial resonator precursor, which includes a bottom electrode and an initial ferroelectric layer over the bottom electrode. The initial ferroelectric layer is formed of a ferroelectric material having a box-shape P-E curve. Next, a patterned bias electrode structure is provided on a periphery of a top surface of the initial ferroelectric layer. Herein, a region of the initial resonator precursor, within which the patterned bias electrode structure is located is a BO region. The initial ferroelectric layer has an initial polarization, and includes an initial ferroelectric BO portion, which is confined within the BO region, and a ferroelectric central portion, which is surrounded by the initial ferroelectric BO portion and not covered by the patterned bias electrode structure. The initial ferroelectric BO portion includes a first part, which is aligned and underneath the patterned bias electrode structure, and a second part, which is not covered by the patterned bias electrode structure. A direct current (DC) bias voltage is then applied between the patterned bias electrode structure and the bottom electrode to convert the initial ferroelectric layer into a ferroelectric layer, which includes a ferroelectric BO portion converted from the initial ferroelectric BO portion and the ferroelectric central portion surrounded by the ferroelectric BO portion. The ferroelectric central portion remains the initial polarization and is configured to provide a resonance of the BAW resonator. The first part of the initial ferroelectric BO portion is converted to an antiparallel part with a first polarization within the ferroelectric BO portion, while the second part of the initial ferroelectric BO portion remains the initial polarization and forms a parallel part within the ferroelectric BO portion. The DC bias voltage is selected, such that an electric field between the patterned bias electrode structure and the bottom electrode results in the first polarization of the antiparallel part being opposite the initial polarization. The first polarization of the antiparallel part and the initial polarization of the parallel part at least partially cancel each other out, such that an absolute value of a combined polarization of the ferroelectric BO portion is smaller than an absolute value of the initial polarization of the ferroelectric central portion.

According to one embodiment, the method further includes removing the DC bias voltage, removing the patterned bias electrode structure, and providing a top electrode structure over a top surface of the ferroelectric layer.

In one embodiment of the method, the top electrode structure includes a top electrode base over the ferroelectric layer and a BO ring protruding from a periphery of the top electrode base. The BO ring is confined in the BO region and the ferroelectric central portion is not covered by the BO ring.

In one embodiment of the method, the top electrode structure has a flat shape.

In one embodiment of the method, after the DC bias voltage is removed, the absolute value of the combined polarization of the ferroelectric BO portion is constant.

In one embodiment of the method, the combined polarization of the ferroelectric BO portion is a zero polarization.

In one embodiment of the method, the ferroelectric material is scandium aluminum nitride (ScₓAl₁₋ₓN) and the P-E curve of ScₓAl₁₋ₓN is dependent on a scandium concentration x.

In one embodiment of the method, the patterned bias electrode structure includes a number of electrode rings with a gap between adjacent ones of the electrode rings. Each electrode ring has a closed ring shape in the horizontal plane.

In one embodiment of the method, the patterned bias electrode structure includes a number of electrode elements, each of which is in the shape of a bar, rectangle, square, circle, or oval in the horizontal plane. The electrode elements surround the ferroelectric central portion and are parallel to each other at each side of the periphery of the top surface of the initial ferroelectric layer.

According to one embodiment, a system includes radio frequency (RF) input circuitry, RF output circuitry, and filter circuitry, which includes at least one BAW resonator connected between the RF input circuitry and the RF output circuitry. The at least one BAW resonator includes a bottom electrode, a top electrode structure, and a ferroelectric layer vertically sandwiched between the bottom electrode and the top electrode structure. Herein, the ferroelectric layer is formed of a ferroelectric material, which has a box-shape polarization-electric field (P-E) curve. The ferroelectric layer includes a ferroelectric border (BO) portion positioned at a periphery of the ferroelectric layer and a ferroelectric central portion surrounded by the ferroelectric BO portion. The ferroelectric BO portion includes an antiparallel part with a first polarization and a parallel part with a second polarization, which is in an opposite direction from the first polarization. The first polarization of the antiparallel part and the second polarization of the parallel part at least partially cancel each other out, such that an absolute value of a combined polarization of the ferroelectric BO portion is smaller than an absolute value of a central polarization of the ferroelectric central portion. The ferroelectric central portion is configured to provide a resonance of the BAW resonator.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a cross-section view of a conventional bulk acoustic wave (BAW) resonator.

FIG. 2 illustrates a typical 1−|S₁₁|₂ response of the BAW resonator shown in FIG. 1.

FIG. 3A illustrates an exemplary polarization-electric field (P-E) curve of scandium aluminum nitride (ScAlN).

FIG. 3B illustrates exemplary different P-E curves of ScAlN dependency on scandium concentration.

FIGS. 4A and 4B illustrate a ferroelectric-based BAW resonator with zero or low electromechanical coupling at a border (BO) region according to some embodiments of the present disclosure.

FIGS. 5A-5E illustrate different configurations of a ferroelectric layer within the ferroelectric-based BAW resonator according to some embodiments of the present disclosure.

FIG. 6 illustrates a comparison of electrical impedance magnitude as a function of frequency for both the conventional BAW resonator shown in FIG. 1 and the ferroelectric-based BAW resonator shown in FIGS. 4A and 4B.

FIGS. 7-11 illustrate an exemplary procedure to implement the ferroelectric-based BAW resonator shown in FIG. 4B according to some embodiments of the present disclosure.

FIGS. 12-13 illustrate other configurations of the ferroelectric-based BAW resonator according to some embodiments of the present disclosure.

FIG. 14 illustrates a block diagram of an example system that includes at least one BAW filter, which is implemented by one or more ferroelectric-based BAW resonators as shown in FIGS. 4A-4B, 5A-5E, and 11-12.

FIG. 15 illustrates a block diagram of an example communication device that includes at least one BAW filter, which is implemented by one or more ferroelectric-based BAW resonators as shown in FIGS. 4A-4B, 5A-5E, and 11-12.

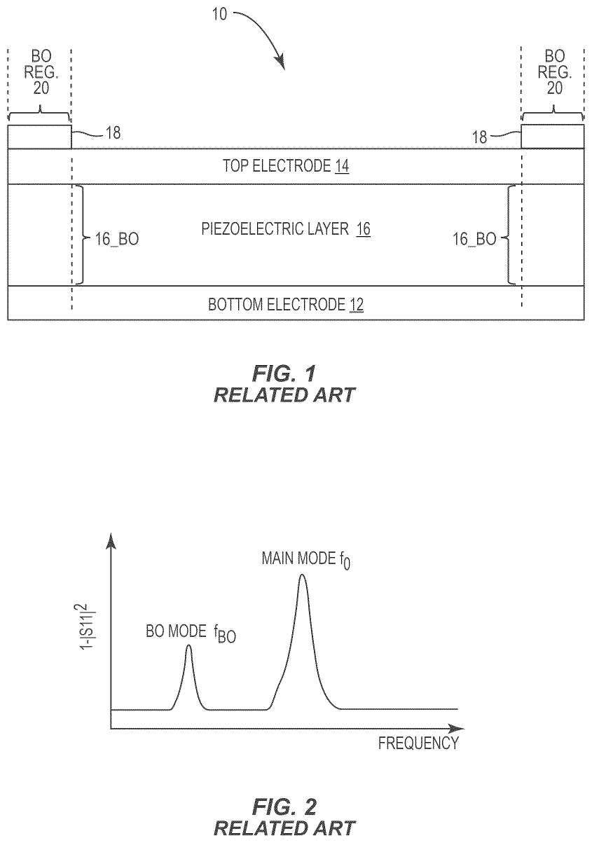

It will be understood that for clear illustrations, FIGS. 1-15 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

An electromechanical coupling coefficient Kₑ² of a bulk acoustic wave (BAW) resonator, such as a thin film bulk acoustic resonator (FBAR) or a solidly mounted resonator (SMR), is a function of a piezoelectric coefficient d of a transduction layer of the BAW resonator, and the piezoelectric coefficient dis proportional to a polarization P of the transduction layer of the BAW resonator. Therefore, once the polarization P of the transduction layer varies, the piezoelectric coefficient d will change accordingly, and consequently, the electromechanical coupling coefficient Kₑ² of the BAW resonator will change as well.

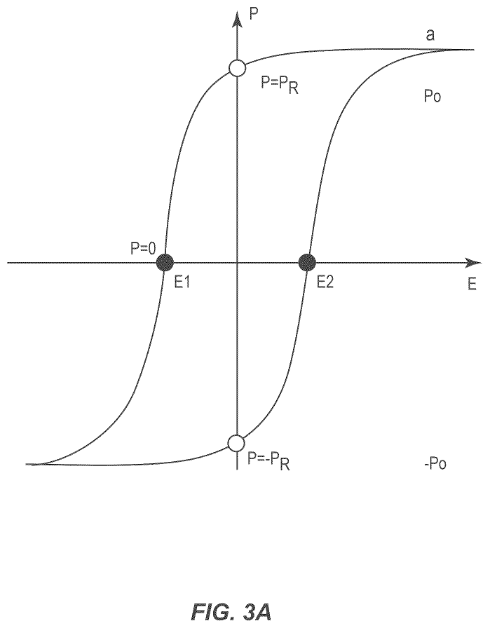

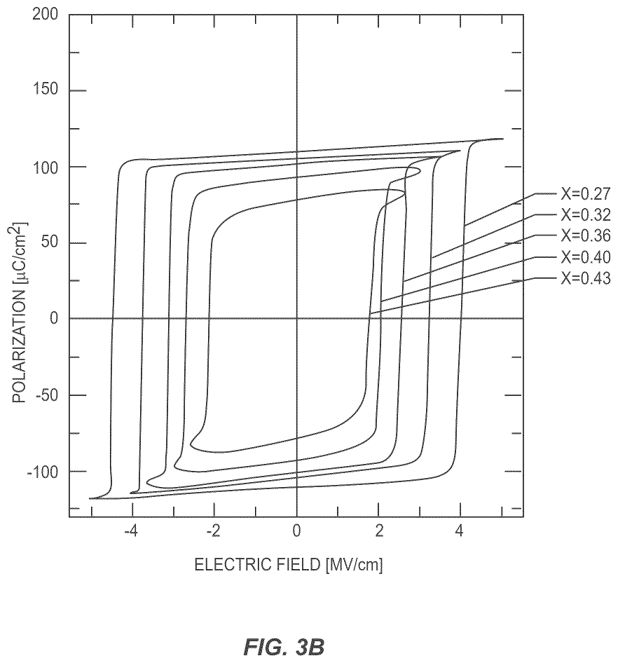

FIG. 3A illustrates a simplified polarization-electric field (P-E) curve (i.e., hysteresis loop) of a ferroelectric material (e.g., scandium aluminum nitride). It is clear that the polarization P of the ferroelectric material can be adjusted by changing the electric field E across the ferroelectric material. A variation amount of the polarization P is determined according to a variation amount of the electric field across the ferroelectric material. Herein, changing the electric field across the ferroelectric material may be implemented by applying different direct current (DC) bias voltages to the ferroelectric material. By applying a particular DC bias voltage to the ferroelectric material, the polarization P of the ferroelectric material can achieve a particular value. Each DC bias voltage corresponds to one polarization, depending on a previously applied electric field (i.e., previously applied DC bias voltage). For instance (e.g., moving in a counterclockwise direction), changing the electric field across the ferroelectric material from 0 to E1 (i.e., by applying a particular DC bias voltage to the ferroelectric material), the polarization P of the ferroelectric material can be moved from P=P_{R} to P=0. As such, the piezoelectric coefficient d of the ferroelectric material can be zero, and the electromechanical coupling coefficient Kₑ² of the BAW resonator that utilizes the ferroelectric material in the transduction layer, can be zero. In another instance (e.g., moving in a clockwise direction), changing the electric field across the ferroelectric material from E2 to 0, the polarization P of the ferroelectric material can be moved from P=0 to P=−P_{R}.

Notice that, once the polarization P of the ferroelectric material achieves a desired value (i.e., the electromechanical coupling coefficient Kₑ² achieves a desired value), there is no need for the DC bias voltage to remain applied to the ferroelectric material. After removing the DC bias voltage, the polarization P of the ferroelectric material (i.e., the electromechanical coupling coefficient Kₑ² of the ferroelectric material) will remain at that desired value until another DC bias voltage is applied to the ferroelectric material.

Scandium aluminum nitride (ScₓAl₁₋ₓN) is an exemplary ferroelectric material. FIG. 3B illustrates different exemplary P-E curves of ScₓAl₁₋ₓN dependent on a scandium concentration x. When the scandium concentration x=0.27, the electric field E across ScₓAl₁₋ₓ N requires −4.5/4 MV/cm to achieve the polarization P of ScₓAl₁₋ₓN equal to zero; when the scandium concentration x=0.32, the electric field E across ScₓAl₁₋ₓN requires −3.8/3.3 MV/cm to achieve the polarization P of ScₓAl₁₋ₓN equal to zero; when the scandium concentration x=0.36, the electric field E across ScₓAl₁₋ₓN requires −3/2.5 MV/cm to achieve the polarization P of ScₓAl₁₋ₓN equal to zero; when the scandium concentration x=0.40, the electric field E across ScₓAl₁₋ₓN requires −2.6/2.1 MV/cm to achieve the polarization P of ScₓAl₁₋ₓN equal to zero; and when the scandium concentration x=0.43, the electric field E across ScₓAl₁₋ₓN requires −2.1/1.8 MV/cm to achieve the polarization P of ScₓAl₁₋ₓN equal to zero (moving in a counterclockwise direction in the P-E curves). These electric field E values can change and depend on the deposition condition of the ferroelectric material (e.g., ScₓAl₁₋ₓN).

With a same electric field E (applying a same DC bias voltage), the polarization P of ScₓAl₁₋ₓN will have different values and/or different directions due to the scandium concentration x. For instance, when the electric field E is-1.5 MV/cm, the polarization P of Sc_{0.27}Al_{0.73}N is 105 μC/cm², while the polarization P of Sc_{0.43}Al_{0.57}N is 70 μC/cm². As such, the electromechanical coupling coefficient Kₑ² of the ferroelectric material, which is dependent on the polarization P of the ferroelectric material, may also have different values due to the scandium concentration x.

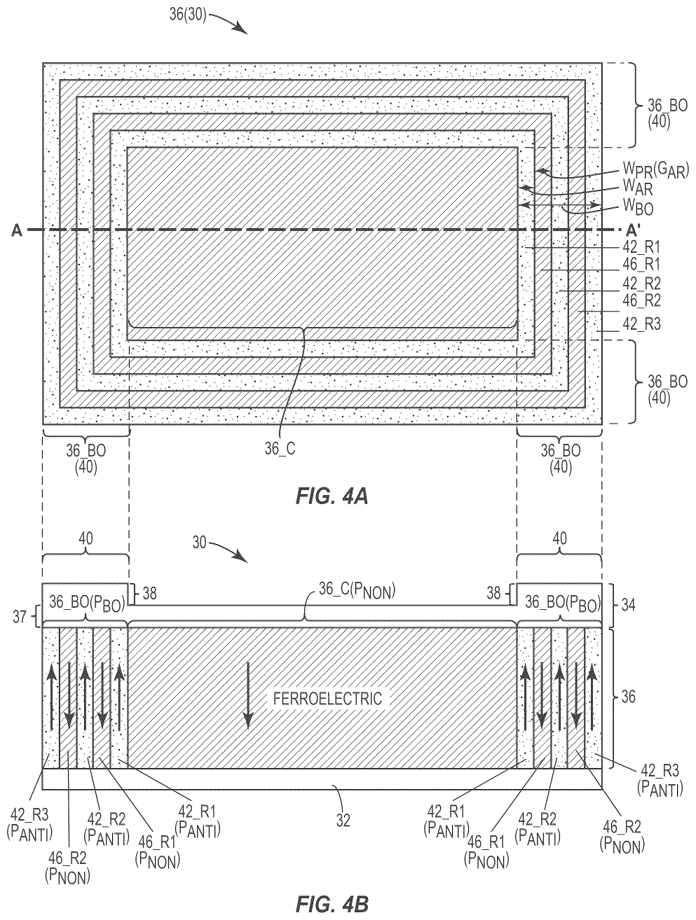

FIGS. 4A and 4B illustrate a ferroelectric-based BAW resonator 30 with zero or low electromechanical coupling at a border region according to some embodiments of the present disclosure. FIG. 4A illustrates a top view of the ferroelectric-based BAW resonator 30 (without a top electrode for clarity), while FIG. 4B shows a cross-section view along a dashed line A-A′ in FIG. 4A. The ferroelectric-based BAW resonator 30 includes a bottom electrode 32, a top electrode structure 34, and a ferroelectric layer 36 sandwiched between the bottom electrode 32 and the top electrode structure 34.

In detail, the bottom electrode 32 may be composed of one or more electrode layers (not shown) and includes at least one metal or alloy, such as Tungsten, Aluminum Copper, and the like. The top electrode structure 34 includes a top electrode base 37 over the ferroelectric layer 36 and a border (BO) ring 38 protruding from a periphery of the top electrode base 37. Notably, a region of the ferroelectric-based BAW resonator 30, within which the BO ring 38 is located is referred to herein as a BO region 40. The top electrode base 37 may be composed of one or more electrode layers (not shown) and includes at least one metal or alloy, such as Tungsten, Aluminum Copper, and the like. The BO ring 38 may be composed of one or more ring layers (not shown) and includes at least one metal or alloy, such as Tungsten, Aluminum Copper, and the like. Each of the bottom electrode 32 and the top electrode base 37 has a thickness depending on the main resonant frequency of the ferroelectric-based BAW resonator 30. The BO ring 38 is configured to confine the energy inside the ferroelectric-based BAW resonator 30 (i.e., inside the ferroelectric layer 36) and prevent laterally propagating standing waves.

The ferroelectric layer 36 is formed of a ferroelectric material, which has a box-shape P-E curve (e.g., as shown in FIG. 3A), such as ScₓAl₁₋ₓN, Lead Zirconate Titanate (PZT), Lead titanate (PTO), Barium Titanate (BTO), Hafnium Oxide (HfO₂) or the like. In one embodiment, when the ferroelectric layer 36 is formed of ScₓAl₁₋ₓN, the scandium concentration x might be between 0.1 and 0.8, such as x=0.27, x=0.32, x=0.36, x=0.40, or x=0.43. Herein, the ferroelectric layer 36 includes a ferroelectric BO portion 36_BO with a BO width WBO, which is confined within the BO region 40 and aligned underneath the BO ring 38, and a ferroelectric central portion 36_C, which is surrounded by the ferroelectric BO portion 36_BO and not covered by the BO ring 38. The ferroelectric BO portion 36_BO has an effectively zero/small polarization PBO (i.e., a combined polarization of the entire ferroelectric BO portion 36_BO is zero/small), and the ferroelectric central portion 36_C has a nonzero polarization P_{NON} (e.g., indicated by a downward arrow), where an absolute value of the combined polarization of the ferroelectric BO portion 36_BO is less than an absolute value of the polarization of the ferroelectric central portion 36_C (|P_{BO}|<|P_{NON}|). Thus, the ferroelectric BO portion 36_BO has an effectively zero/small electromechanical coupling coefficient K_{e_BO}² (i.e., a combined electromechanical coupling coefficient of the entire ferroelectric BO portion 36_BO is zero/small), which is less than a nonzero electromechanical coupling coefficient K_{e_NON}² of the ferroelectric central portion 36_C. Due to the effectively zero/small electromechanical coupling coefficient K_{e_BO}² of the ferroelectric BO portion 36_BO, there will be no or low BO spurious resonance modes in the ferroelectric-based BAW resonator 30. In addition, the effectively zero/small polarization PBO (the effectively zero/small electromechanical coupling coefficient K_{e_BO}²) of the ferroelectric BO portion 36_BO can also help confine the energy inside the ferroelectric-based BAW resonator 30 and reduce laterally propagating standing waves, so as to enhance a quality factor of the ferroelectric-based BAW resonator 30. The ferroelectric central portion 36_C, which has the nonzero electromechanical coupling coefficient K_{e_NON}², is configured to provide a main resonance of the ferroelectric-based BAW resonator 30 (when an alternating current voltage is applied between the top electrode structure 34 and the bottom electrode 32).

The effectively zero/small polarization PBO (the effectively zero/small electromechanical coupling coefficient K_{e_BO}²) of the ferroelectric BO portion 36_BO is achieved by an antiparallel part 42 and a parallel part 46 having different polarizations within the ferroelectric BO portion 36_BO. In some embodiments, the antiparallel part 42 has an opposite polarization P_{ANTI} (e.g., indicated by upward arrows) to the ferroelectric central portion 36_C, while the parallel part 46 has the same polarization P_{NON} (e.g., indicated by downward arrows) as the ferroelectric central portion 36_C. The nonzero polarization P_{NON} and the opposite polarization P_{ANTI} have different directions with a same or different absolute value. The polarization P_{ANTI} of the antiparallel part 42 and the polarization P_{NON} of the parallel part 46 at least partially cancel each other out (e.g., substantially cancel each other out), which results in the combined polarization of the ferroelectric BO portion 36_BO being very small or zero.

For the purpose of this illustration, the antiparallel part 42 includes three antiparallel rings 42_R (e.g., a first antiparallel ring 42_R1, a second antiparallel ring 42_R2, and a third antiparallel ring 42_R3), while the parallel part 46 includes two parallel rings 46_R (e.g., a first parallel ring 46_R1 and a second parallel ring 46_R2) alternating with the antiparallel rings 42_R in a horizontal plane. Herein, each antiparallel ring 42_R may have a same width W_{AR} (e.g. 0<W_{AR}<=4 μm), and each parallel ring 46_R may have a same width W_{PR} (e.g. 0<W_{PR}<=4 μm), such that the antiparallel rings 42_R are equally spaced with a fixed GAR (i.e., W_{PR}=G_{AR}). The first antiparallel ring 42_R1 surrounds the ferroelectric central portion 36_C (may or may not be in contact with the ferroelectric central portion 36_C), the first parallel ring 46_R1 surrounds the first antiparallel ring 42_R1, the second antiparallel ring 42_R2 surrounds the first parallel ring 46_R1, the second parallel ring 46_R2 surrounds the second antiparallel ring 42_R2, and the third antiparallel ring 42_R3 surrounds the second parallel ring 46_R2. Each antiparallel ring 42_R has a closed ring shape in the horizontal plane, extends vertically through the ferroelectric BO portion 36_BO, and has the opposite polarization P_{ANTI} (e.g., indicated by one upward arrow) to the ferroelectric central portion 36_C. Each parallel ring 46_R has a closed ring shape in the horizontal plane, extends vertically through the ferroelectric BO portion 36_BO, and has the same polarization P_{NON} (e.g., indicated by one downward arrow) as the ferroelectric central portion 36_C. The polarization of the antiparallel rings 42_R and the polarization of the parallel rings 46_R at least partially cancel each other out (e.g., may substantially cancel each other out), and the combined polarization of the ferroelectric BO portion 36_BO is very small or zero.

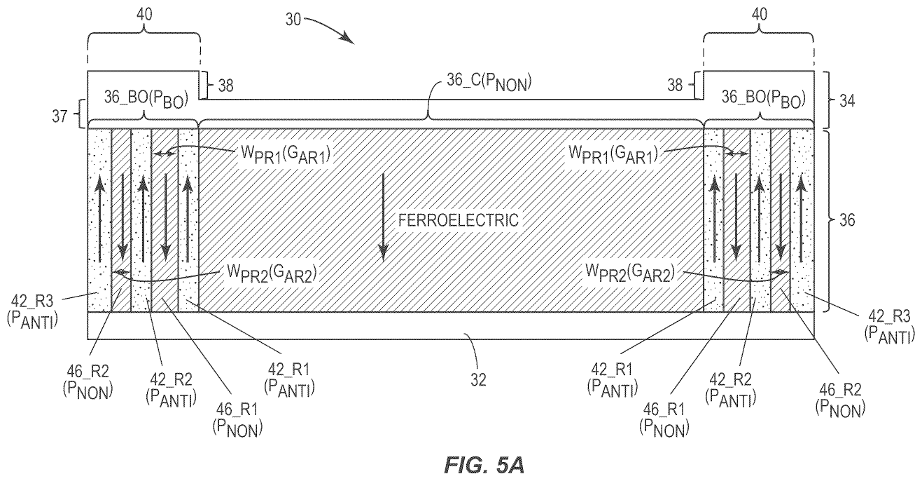

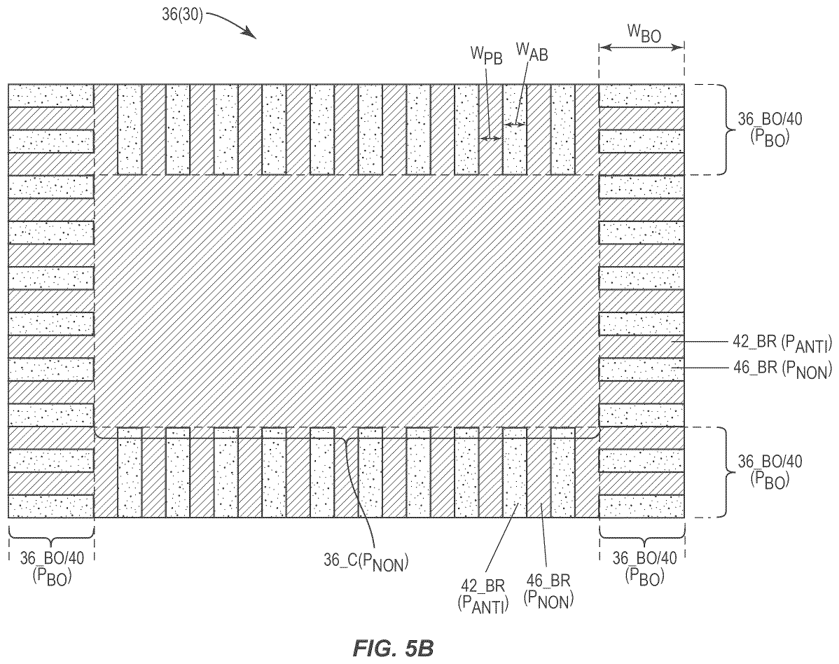

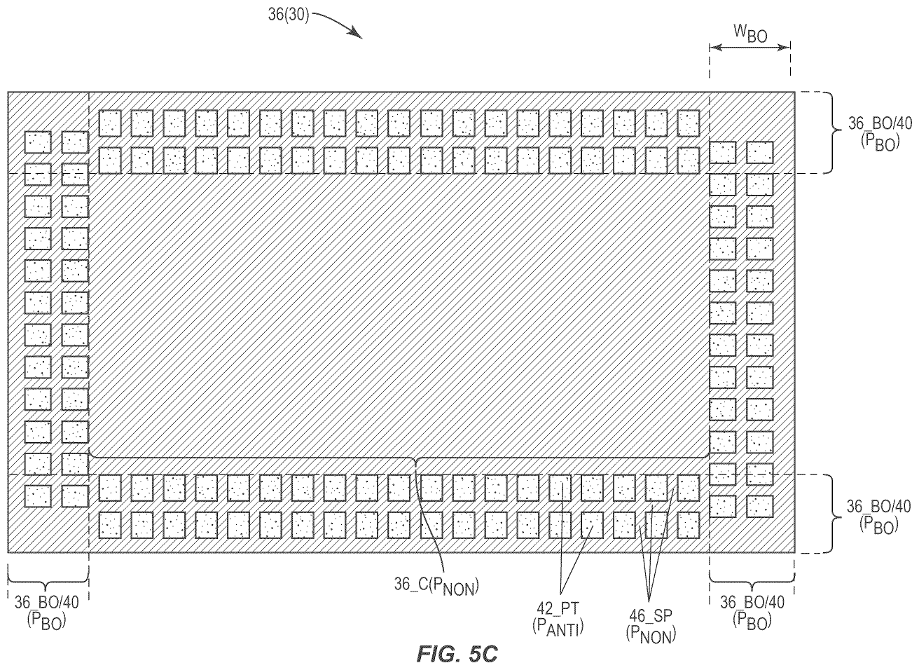

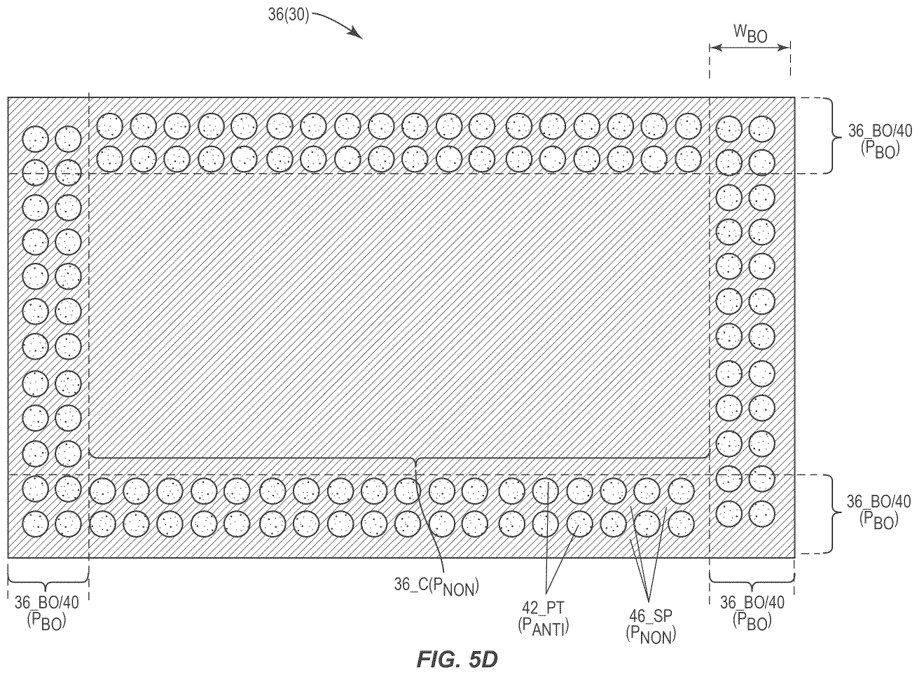

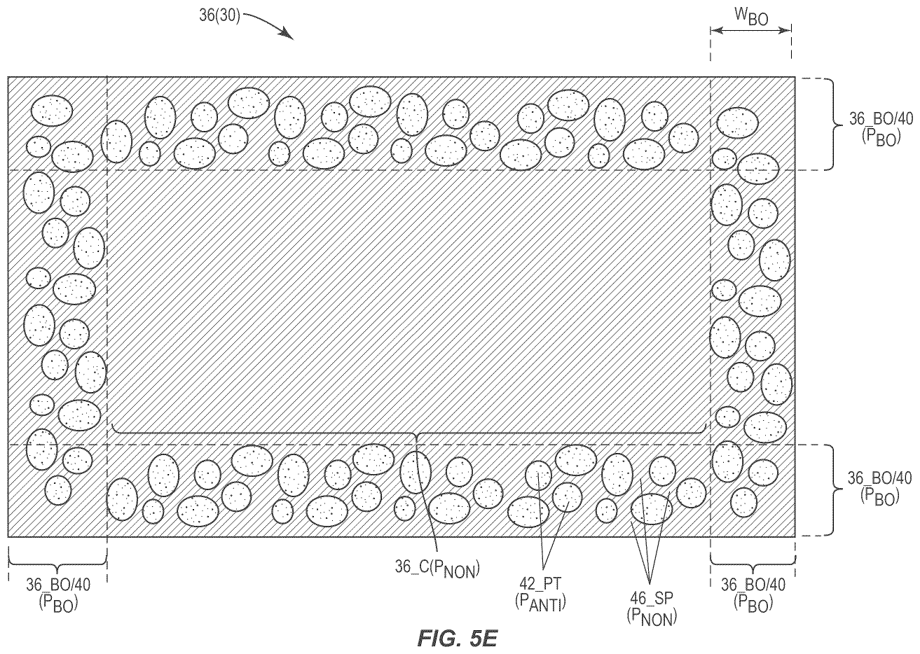

In different applications, the antiparallel part 42 may include fewer or more antiparallel rings 42_R, and the parallel part 46 may accordingly include fewer or more parallel rings 46_R. Each antiparallel ring 42_R may have a different width and/or each parallel ring 46_R may have a different width. As such, the antiparallel rings 42_R and/or the parallel ring 46_R may not be equally spaced. As illustrated in FIG. 5A, the antiparallel rings 42_R are not equally spaced, where the antiparallel rings 42_R have a lower density adjacent to the ferroelectric central portion 36_C and have a higher density away from the ferroelectric central portion 36_C. For the purpose of this illustration, the first antiparallel ring 42_R1 and the second antiparallel ring 42_R2 have a first space gap G_{AR1} (i.e, a width W_{PR1} of the first parallel ring 46_R1), while the second antiparallel ring 42_R2 and the third antiparallel ring 42_R3 have a second space gap G_{AR2} (i.e, a width W_{PR2} of the second parallel ring 46_R2), which is smaller than the first space gap G_{AR1}. The density variation of the antiparallel rings 42_R may result in a varying effect of polarization cancellation within the ferroelectric BO portion 36_BO. Typically, a lower density of the antiparallel rings 42_R leads to less polarization cancellation, while a higher density of the antiparallel rings 42_R leads to more polarization cancellation. As such, the combined polarization P_{BO} within the ferroelectric BO portion 36_BO may decrease from an interior side of the ferroelectric BO portion 36_BO towards an outer edge of the ferroelectric BO portion 36_BO. For a non-limiting example, the combined polarization P_{BO} within the ferroelectric BO portion 36_BO may decrease from the polarization P_{NON} of the ferroelectric central portion 36_C to zero. In consequence, the ferroelectric BO portion 36_BO will also have a varied combined electromechanical coupling coefficient K_{e_BO}² (reduces from the interior side of the ferroelectric BO portion 36_BO towards the outer edge of the ferroelectric BO portion 36_BO). The minimum value of the varied combined electromechanical coupling coefficient K_{e_BO}² might be zero.

Furthermore, the ferroelectric BO portion 36_BO/the ferroelectric layer 36 may have a different configuration, for example the antiparallel part 42 may have different patterns/shapes (e.g., discrete bars, discrete squares, discrete circles, discrete ovals, or the like) other than the closed rings in the horizontal plane. For a non-limiting example, the antiparallel part 42 may include a number of discrete antiparallel bars 42_BR, and the parallel part 46 includes a number of discrete parallel bars 46_BR alternating with the antiparallel bars 42_BR in the horizontal plane (only a few antiparallel bars and parallel bars are labeled with reference numbers for clarity), as illustrated in FIG. 5B. Each antiparallel bar 42_BR may have a rectangular shape in the horizontal plane, may extend through the ferroelectric BO portion 36_BO in the horizontal plane and extend vertically through the ferroelectric BO portion 36_BO (not shown). Each antiparallel bar 42_BR may have the opposite polarization P_{ANTI} to the ferroelectric central portion 36_C. The antiparallel bars 42_BR surround the ferroelectric central portion 36_C and are parallel to each other at each periphery side of the ferroelectric layer 36 (e.g., parallel to each other within each side of the ferroelectric BO portion 36_BO). Each parallel bar 46_BR may also have a rectangular shape in the horizontal plane, may extend through the ferroelectric BO portion 36_BO in the horizontal plane and may extend vertically through the ferroelectric BO portion 36_BO (not shown). Each parallel bar 46_BR may have the same polarization P_{NON} as the ferroelectric central portion 36_C. The parallel bars 46_BR also surround the ferroelectric central portion 36_C and are parallel to each other at each periphery side of the ferroelectric layer 36 (e.g., parallel to each other within each side of the ferroelectric BO portion 36_BO). Each antiparallel bar 42_BR may have a same bar width W_{AB} or different bar widths between 0 and 4 μm, and each parallel bar 46_BR may have a same bar width WPB or different bar widths between 0 and 4 μm (i.e. the antiparallel bars 42_BR may be equally spaced or unequally spaced). Herein, the polarization of the antiparallel bars 42_BR and the polarization of the parallel bars 46_BR at least partially cancel each other out (e.g., substantially cancel each other out), and the combined polarization of the ferroelectric BO portion 36_BO is very small or zero.

FIGS. 5C-5E show other exemplary patterns/configurations of the antiparallel part 42 in the horizontal plane. The antiparallel part 42 may include a number of discrete antiparallel posts 42_PT dispersed at the periphery of the ferroelectric layer 36 in the horizontal plane. The antiparallel posts 42_PT are separated from each other by parallel spacers 46_SP of the parallel part 46. Herein, the parallel spacers 46_SP may be connected to each other and have different shapes due to the layout of the antiparallel posts 42_PT (only a few antiparallel posts and parallel spacers are labeled with reference numbers for clarity). The antiparallel posts 42_PT may have the opposite polarization P_{ANTI} to the ferroelectric central portion 36_C, while the parallel spacers 46_SP may have the same polarization P_{NON} as the ferroelectric central portion 36_C.

As illustrated in FIG. 5C, the antiparallel part 42 includes two rows of antiparallel posts 42_PT at each periphery side of the ferroelectric layer 36 (i.e., within the ferroelectric BO portion 36_BO) in the horizontal plane and surrounds the ferroelectric central portion 36_C. The antiparallel posts 42_PT may be equally spaced in the horizontal plane, and each antiparallel post 42_PT may have a uniform square/rectangular shape in the horizontal plane and may extend vertically through the ferroelectric BO portion 36_BO (not shown). In some applications, the antiparallel part 42 may include more rows of antiparallel posts 42_PT at each periphery side of the ferroelectric layer 36 (not shown). In some applications, each antiparallel post 42_PT may have a different shape in the horizontal plane, such as a circle/oval as illustrated in FIG. 5D. In some applications, the antiparallel posts 42_PT may have more than one shape/size in the horizontal plane (e.g., having ovals and circles of different sizes), and/or the antiparallel posts 42_PT may be spaced unequally in the horizontal plane (i.e., the parallel spacers 46_SP may have different shapes and dimensions) as illustrated in FIG. 5E.

It is noted that the antiparallel part 42 may be composed of different antiparallel elements (e.g., the antiparallel rings 42_R, the antiparallel bars 42_BR, and/or antiparallel post 42_PT) with continuous or discrete configurations. The size and/or the shape of these antiparallel elements can vary and is determined by different applications. Regardless of the shape, size, layout and/or the configuration of the antiparallel elements, the antiparallel part 42 is always located at the periphery of the ferroelectric layer 36 in the horizontal plane, surrounding the ferroelectric central portion 36_C, and confined within the ferroelectric BO portion 36_BO. Adjacent antiparallel elements are always separated by a portion of the parallel part 46 (e.g., the parallel ring 46_R, the parallel bar 46_BR, and/or the parallel spacer 46_SP). The polarization of the antiparallel part 42 and the polarization of the parallel part 46 at least partially cancel each other out (e.g., substantially cancel each other out), and the combined polarization of the ferroelectric BO portion 36_BO is very small or zero.

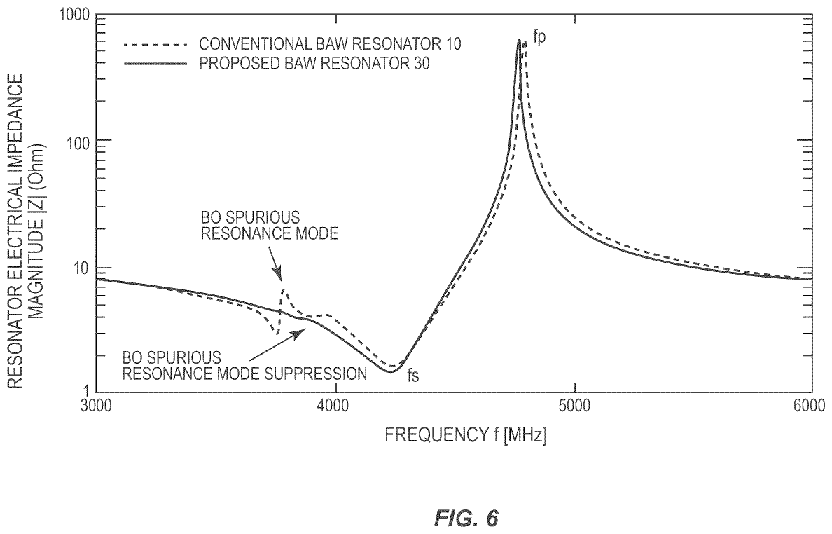

FIG. 6 illustrates a comparison of a resonator electrical impedance magnitude |Z| as a function of frequency f (MHz) for both the conventional BAW resonator 10 shown in FIG. 1 and the ferroelectric-based BAW resonator 30 shown in FIGS. 4A and 4B. It is clearly shown that the ferroelectric-based BAW resonator 30 works properly with a resonance frequency fs around 4250 MHz and an antiresonance frequency fp around 4750 MHz without a BO spurious resonance mode. However, the conventional BAW resonator 10 not only has the resonance frequency fs around 4250 MHz and the antiresonance frequency fp around 4750 MHz, but also resonates around 3750 MHz, which is an undesired BO spurious resonance mode caused by the BO ring 18. By utilizing the antiparallel part 42, the ferroelectric-based BAW resonator 30 can achieve a zero/small coupling BO region, which will significantly compress the undesired BO spurious resonance mode.

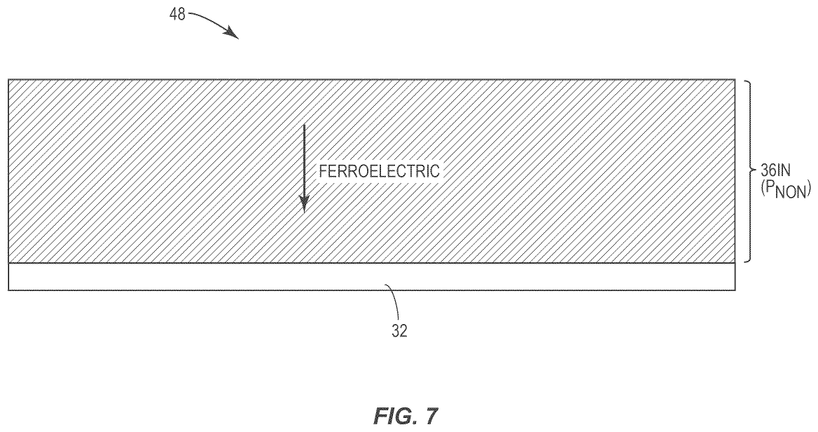

FIGS. 7-11 graphically illustrate an exemplary process for implementing the ferroelectric-based BAW resonator 30 shown in FIG. 4B according to some embodiments of the present disclosure. Although the process steps are illustrated in a series, the process steps are not necessarily order dependent. Some steps may be done in a different order than that presented. Further, processes within the scope of this disclosure may include fewer or more steps than those illustrated in FIGS. 7-11.

As illustrated in FIG. 7, the process begins with an initial resonator precursor 48, which includes the bottom electrode 32 and an initial ferroelectric layer 36IN over the bottom electrode 32. The initial ferroelectric layer 36IN is formed of a ferroelectric material, which has a box-shape P-E curve (e.g., as shown in FIG. 3A), such as ScₓAl₁₋ₓN, PZT, PTO, BTO, HfO₂, or the like. In one embodiment, when the initial ferroelectric layer 36IN is formed of ScₓAl₁₋ₓN, the scandium concentration x might be between 0.1 and 0.8, such as x=0.27, x=0.32, x=0.36, x=0.40, or x=0.43. Herein, the entire initial ferroelectric layer 36IN has the initial non-zero polarization P_{NON} (e.g., indicated by a downward arrow).

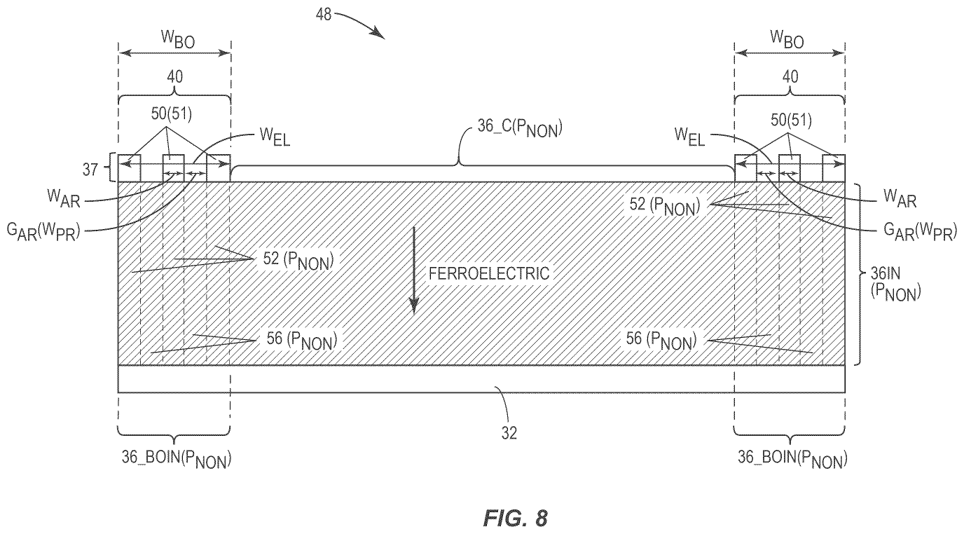

Next, a patterned bias electrode structure 50 is provided on a periphery of a top surface of the initial ferroelectric layer 36IN, as illustrated in FIG. 8. Herein, a region of the initial resonator precursor 48, within which the patterned bias electrode structure 50 is located, is referred to as the BO region 40. A total width W_{EL} (e.g., 0<W_{EL}<10 μm) of the patterned bias electrode structure 50 is smaller or equal to the BO width W_{BO} of the BO region 40. The initial ferroelectric layer 36IN is divided into an initial ferroelectric BO portion 36_BOIN, which is confined within the BO region 40 and aligned underneath the patterned bias electrode structure 50, and the ferroelectric central portion 36_C, which is surrounded by the initial ferroelectric BO portion 36_BOIN and not covered by the patterned bias electrode structure 50. The initial ferroelectric BO portion 36_BOIN and the ferroelectric central portion 36_C both have the non-zero polarization P_{NON}. The patterned bias electrode structure 50 may be composed of one or more layers (in a vertical direction, not shown) and includes at least one metal or alloy, such as Tungsten, Aluminum Copper, and the like. A pattern/shape of the patterned bias electrode structure 50 in the horizontal plane is consistent with the pattern/shape of the antiparallel part 42 included in the final resonator and is designed based on the main resonance of the final resonator as well as the material and thickness of the initial ferroelectric layer 36IN.

In this illustration, the patterned bias electrode structure 50 includes three electrode rings 51, each of which has a closed ring shape corresponding to the first antiparallel ring 42_R1, the second antiparallel ring 42_R2, and the third antiparallel ring 42_R3 in the final product, respectively. Each electrode ring 51 may have the same width W_{AR} (i.e., the width of one antiparallel ring 42_R, 0<W_{AR}<=4 μm), and the electrode rings 51 of the patterned bias electrode structure 50 are equally spaced with the fixed G_{AR} (e.g. 0<G_{AR}<=4 μm). Herein, a first part 52 of the initial ferroelectric BO portion 36_BOIN, which is aligned and underneath the patterned bias electrode structure 50, will be used to form the antiparallel part 42 included in the final product. The second part 56 of the initial ferroelectric BO portion 36_BOIN, which is not covered by the patterned bias electrode structure 50, will be used to form the parallel part 46 included in the final product. In different applications, the patterned bias electrode structure 50 may have fewer or more electrode rings 51, the electrode rings 51 may not be equally spaced (i.e., with a varying density, for instance being consistent with the antiparallel bars 42_R illustrated in FIG. 5A), and/or each electrode ring 51 may have a different width. Furthermore, the patterned bias electrode structure 50 may have a number of discrete electrode elements with different patterns/shapes (e.g., discrete bars, discrete rectangles/squares, discrete circles, discrete ovals, or the like) in the horizontal plane (not shown). The patterns/shapes of these discrete electrode elements are consistent with the patterns/shapes of the antiparallel part 42 (e.g. shown in FIGS. 5A-5E) included in the final resonator.

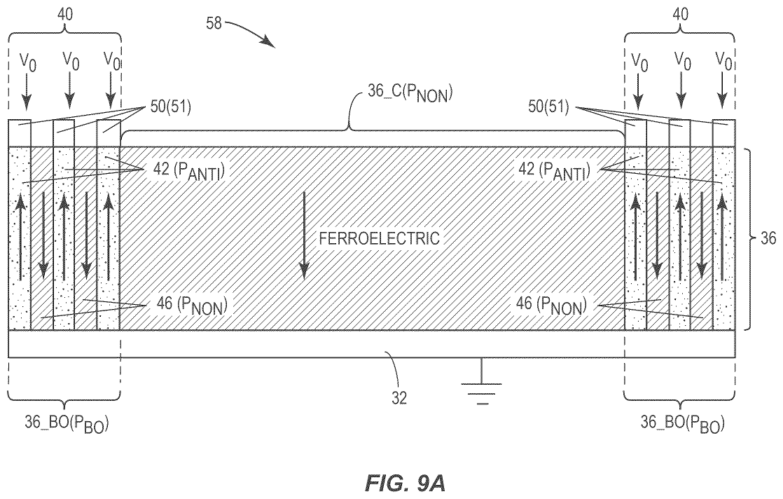

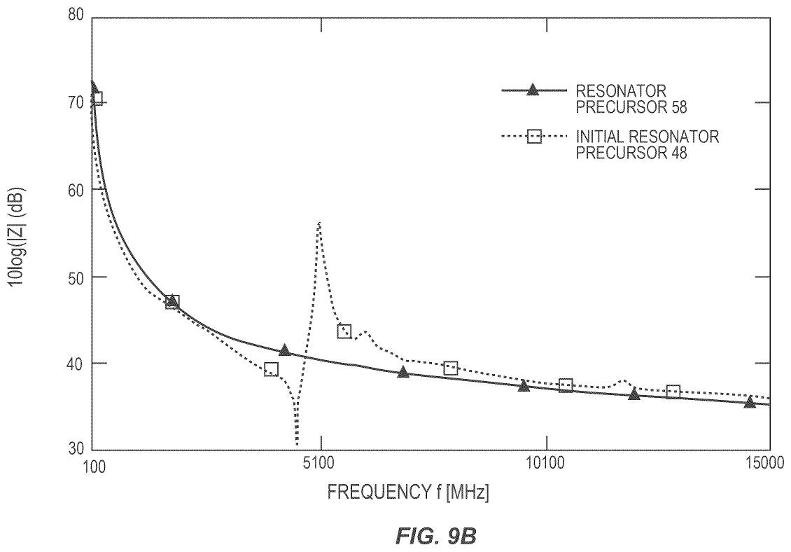

After the patterned bias electrode structure 50 is provided, a DC bias voltage V₀ is applied to the patterned bias electrode structure 50, and the bottom electrode 32 is electrically coupled to ground, such that the initial ferroelectric layer 36IN converts to the ferroelectric layer 36 with the ferroelectric BO portion 36_BO having the effectively zero/small polarization P_{BO} (the initial resonator precursor 48 converts to a resonator precursor 58), as illustrated in FIG. 9A. Herein, the DC voltage V₀ may have a fixed value or vary with time, but always provides an electrical field in an opposite direction from the initial non-zero polarization P_{NON}. As such, the polarization of the first part 52 of the initial ferroelectric BO portion 36_BOIN covered by the patterned bias electrode structure 50 starts to reduce, becomes zero, and eventually grows antiparallel (e.g., indicated by the upward arrows) to the initial non-zero polarization P_{NON}. The first part 52 of the initial ferroelectric BO portion 36_BOIN covered by the patterned bias electrode structure 50 is converted to the antiparallel part 42 with the polarization P_{ANTI} in the ferroelectric BO portion 36_BO. On the other hand, the applied DC bias voltage V₀ barely changes the electric field across the second part 56 of the initial ferroelectric BO portion 36_BOIN uncovered by the patterned bias electrode structure 50, such that the second part 56 of the initial ferroelectric BO portion 36_BOIN remains the same initial non-zero polarization P_{NON} (e.g., indicated by the downward arrows) and forms the parallel part 46 in the ferroelectric BO portion 36_BO. The polarization P_{ANTI} of the antiparallel part 42 and the polarization P_{NON} of the parallel part 46 at least partially cancel each other out (e.g., substantially cancel each other out), and the combined polarization P_{BO} of the ferroelectric BO portion 36_BO is very small or zero.

FIG. 9B illustrates the resonator electrical impedance magnitude |Z| of the initial resonator precursor 48 (shown in FIG. 8) and the resonator precursor 58 (shown in FIG. 9A) with the antiparallel part 42 around the BO spurious resonance frequency (e.g. 5000 MHz). Clearly, without the antiparallel part 42, the initial resonator precursor 48 still resonates significantly around the BO spurious resonance frequency. After applying/utilizing the antiparallel part 42, the undesired BO spurious resonance mode is substantially removed from the resonator precursor 58 (e.g., the resonator precursor 58 does not resonate at the BO spurious resonance frequency).

In some embodiments, if the patterned bias electrode structure 50 includes unequally spaced electrode rings 51 (e.g., the electrode rings 51 have a lower density adjacent to the ferroelectric central portion 36_C and have a higher density away from the ferroelectric central portion 36_C, not shown), the final combined polarization P_{BO} within the ferroelectric BO portion 36_BO may decrease from an interior side of the ferroelectric BO portion 36_BO towards an outer edge of the ferroelectric BO portion 36_BO.

In addition, the applied DC bias voltage V₀ also barely changes the electric field across the ferroelectric central portion 36_C and keeps the same non-zero polarization P_{NON}. In consequence, the ferroelectric BO portion 36_BO has an effectively zero/small electromechanical coupling coefficient K_{e_BO}², which is smaller than a nonzero electromechanical coupling coefficient K_{e_NON}² of the ferroelectric central portion 36_C. The effectively zero/small electromechanical coupling coefficient K_{e_BO}² of the ferroelectric BO portion 36_BO will result in no/low BO spurious resonance, while the nonzero electromechanical coupling coefficient K_{e_NON}² of the ferroelectric central portion 36_C will provide a main resonance of the final resonator. Herein, the DC bias voltage V₀ is carefully selected, so that the electric field between the patterned bias electrode structure 50 and the bottom electrode 32 will lead to the antiparallel polarization of the antiparallel part 42 in the ferroelectric BO portion 36_BO opposite to the initial non-zero polarization P_{NON}. The DC bias voltage V₀ is selected based on the material and thickness of the initial ferroelectric layer 36IN.

Notice that, once the polarization P_{BO} of the ferroelectric BO portion 36_BO becomes zero or a small value, there is no need to retain the DC bias voltage V₀ applied to the ferroelectric BO portion 36_BO. After removing the DC bias voltage V₀, the polarization P_{BO} of the ferroelectric BO portion 36_BO will remain at zero or the small value, until another DC bias voltage is applied to the ferroelectric BO portion 36_BO.

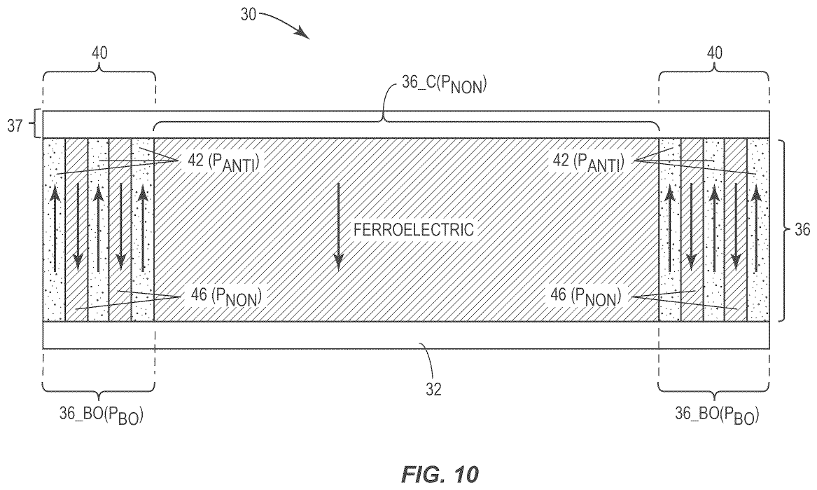

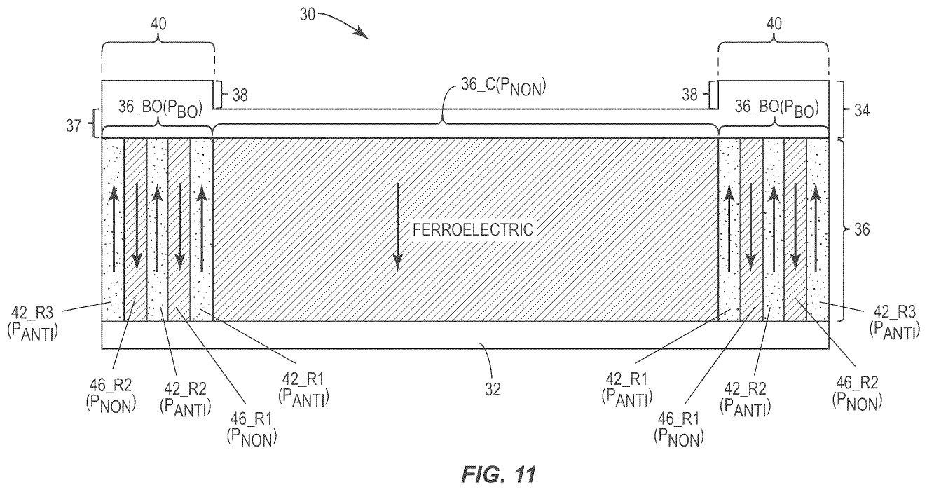

The patterned bias electrode structure 50 is then removed, and the electrode base 37 is formed over the top surface of the ferroelectric layer 36, as illustrated in FIG. 10. The electrode base 37 covers the ferroelectric central portion 36_C and the ferroelectric BO portion 36_BO. The top electrode base 37 may be composed of one or more electrode layers (not shown) and includes at least one metal or alloy, such as Tungsten, Aluminum Copper, and the like. Lastly, the BO ring 38 might be formed over the electrode base 37 to complete the top electrode structure 34 (to complete the ferroelectric-based BAW resonator 30), as illustrated in FIG. 11. The BO ring 38 protrudes from the periphery of the top electrode base 37, and is used as a mass loading component at the perimeter of the ferroelectric-based BAW resonator 30. The BO region 40 is the region within which the BO ring 38 is located.

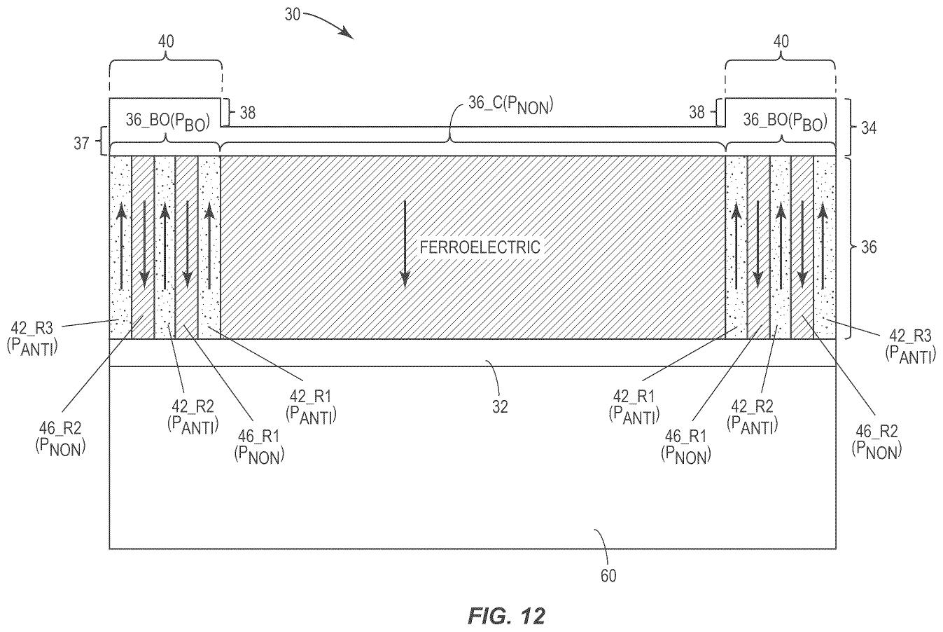

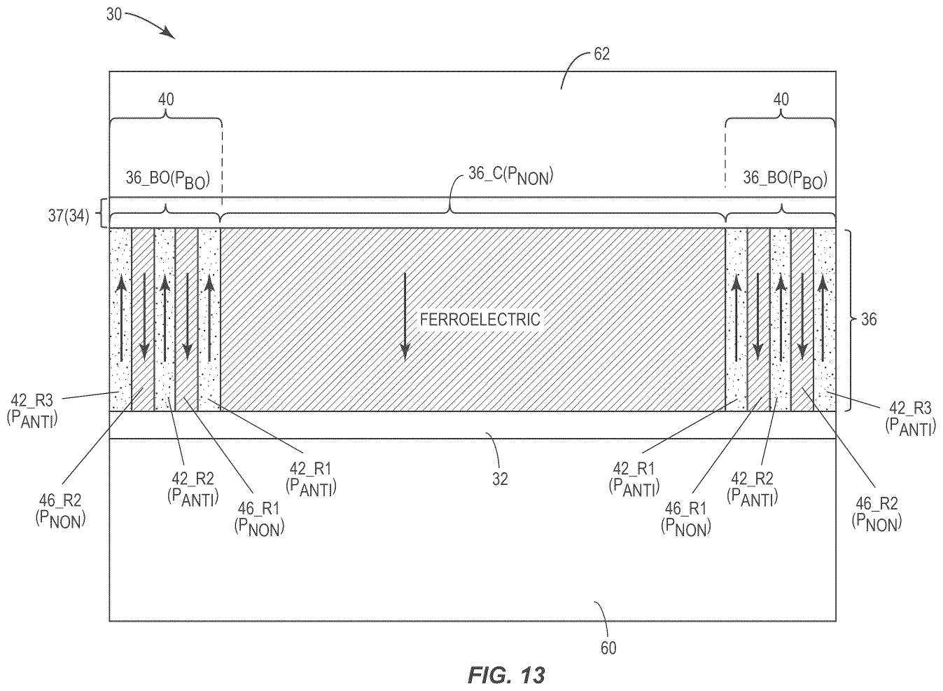

In some applications, the ferroelectric-based BAW resonator 30 may further include one or two reflectors. As illustrated in FIG. 12, in addition to the bottom electrode 32, the top electrode structure 34, and the ferroelectric layer 36, the ferroelectric-based BAW resonator 30 also includes a bottom reflector 60 underneath the bottom electrode 32. The bottom reflector 60 may be a Brag reflector. In some applications, the top electrode structure 34 may only include the electrode base 37 without the BO ring 38 (as shown in FIG. 10) over the ferroelectric layer 36 (not shown). As illustrated in FIG. 13, the ferroelectric-based BAW resonator 30, in addition to the bottom electrode 32, the top electrode base 37 (i.e., the BO ring 38 is omitted in the top electrode structure 34), and the ferroelectric layer 36, also includes the bottom reflector 60 underneath the bottom electrode 32 and a top reflector 62 over the top electrode base 37. The bottom reflector 60 and the top reflector 62 may be Brag reflectors. In some applications, the ferroelectric-based BAW resonator 30 may include the top electrode structure 34 (as shown in FIG. 4B or 11) sandwiched between the ferroelectric layer 36 and the top reflector 62 (not shown).

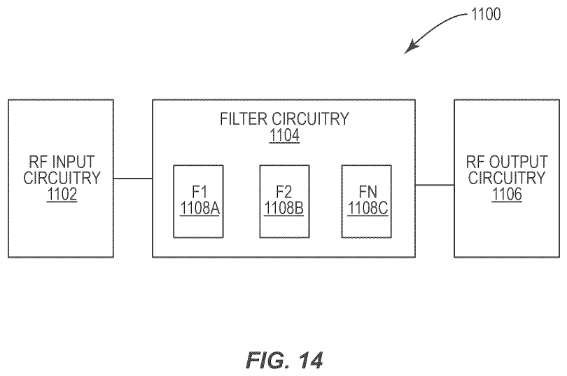

FIG. 14 illustrates a block diagram of an example system 1100 that includes at least one BAW filter, which is implemented by one or more ferroelectric-based BAW resonators 30 as shown in FIGS. 4A-4B, 5A-5E, and 11-12. The system 1100 includes radio frequency (RF) input circuitry 1102, filter circuitry 1104, and RF output circuitry 1106. The filter circuitry 1104 is coupled between the RF input circuitry 1102 and the RF output circuitry 1106. In certain embodiments, the RF input circuitry 1102 includes a transceiver, while RF output circuitry 1106 includes an antenna. For the purpose of this illustration, the filter circuitry 1104 includes three filters 1108A, 1108B, and 1108C. Herein, one or more of the filters 1108A, 1108B, and 1108C may be BAW filters, which are implemented by one or more ferroelectric-based BAW resonators 30. In different applications, the filter circuitry 1104 may include fewer or more filters. In one embodiment, each of the filters 1108A, 1108B, and 1108C may be a lowpass filter or a bandpass filter, and the filters 1108A, 1108B, and 1108C may be connected in a cascaded arrangement. The filter types that are included in the filter circuitry 1104 may be based at least on the rejection requirements of the system 1100. The RF input circuitry 1102 and/or the RF output circuitry 1106 may include additional or different components in other embodiments.

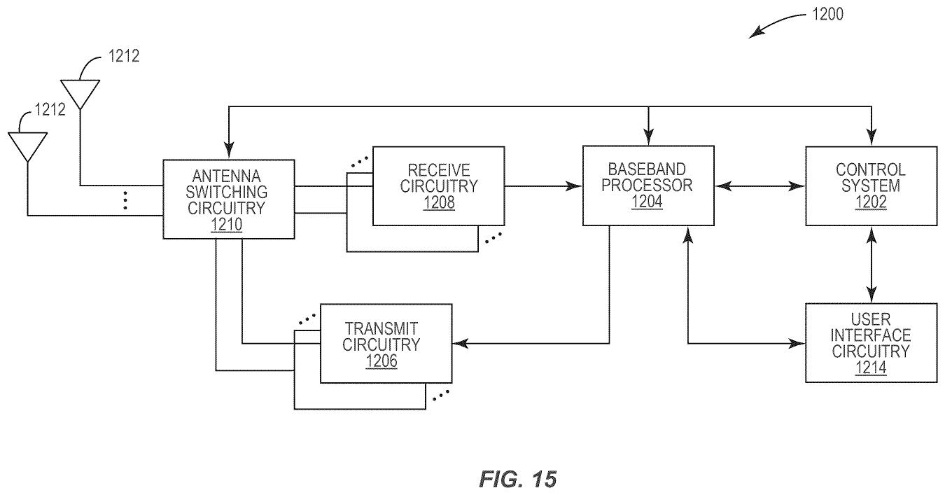

FIG. 15 illustrates a block diagram of an example communication device 1200 that includes at least one BAW filter, which is implemented by one or more ferroelectric-based BAW resonators 30 shown in FIGS. 4A-4B, 5A-5E, and 11-13. The concepts described above may be implemented in various types of communication devices 1200, such as mobile terminals, smart watches, tablets, computers, navigation devices, access points, and like wireless communication devices that support wireless communications, such as cellular, wireless local area network (WLAN), BLUETOOTH, and near field communications. The communication devices 1200 will generally include a control system 1202, a baseband processor 1204, transmit circuitry 1206, receive circuitry 1208, antenna switching circuitry 1210, multiple antennas 1212, and user interface circuitry 1214. In a non-limiting example, the control system 1202 can be a field-programmable gate array (FPGA) or an application-specific integrated circuit (ASIC), as an example. In this regard, the control system 1202 can include at least a microprocessor(s), an embedded memory circuit(s), and a communication bus interface(s). The receive circuitry 1208 receives RF signals via the antennas 1212 and through the antenna switching circuitry 1210 from one or more base stations. A low noise amplifier and a filter of the receive circuitry 1208 cooperate to amplify and remove broadband interference from the received signal for processing. Down conversion and digitization circuitry (not shown) will then down convert the filtered, received signal to an intermediate or baseband frequency signal, which is then digitized into one or more digital streams using an analog-to-digital converter(s) (ADC).

The baseband processor 1204 processes the digitized received signal to extract the information or data bits conveyed in the received signal. This processing typically comprises demodulation, decoding, and error correction operations, as will be discussed in greater detail below. The baseband processor 1204 is generally implemented in one or more digital signal processors (DSPs) and ASICs.

For transmission, the baseband processor 1204 receives digitized data, which may represent voice, data, or control information, from the control system 1202, which it encodes for transmission. The encoded data is output to the transmit circuitry 1206, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 1212 through the antenna switching circuitry 1210. The multiple antennas 1212 and the replicated transmit and receive circuitries 1206, 1208 may provide spatial diversity. Modulation and processing details will be understood by those skilled in the art.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A bulk acoustic wave (BAW) resonator, comprising:
a bottom electrode;
a top electrode structure; and
a ferroelectric layer vertically sandwiched between the bottom electrode and the top electrode structure, wherein:
the ferroelectric layer is formed of a ferroelectric material, which has a box-shape polarization-electric field (P-E) curve;
the ferroelectric layer includes a ferroelectric border (BO) portion positioned at a periphery of the ferroelectric layer and a ferroelectric central portion surrounded by the ferroelectric BO portion;
the ferroelectric BO portion includes an antiparallel part with a first polarization and a parallel part with a second polarization, which is in an opposite direction from the first polarization, wherein the first polarization of the antiparallel part and the second polarization of the parallel part at least partially cancel each other out, such that an absolute value of a combined polarization of the ferroelectric BO portion is smaller than an absolute value of a central polarization of the ferroelectric central portion; and
the ferroelectric central portion is configured to provide a resonance of the BAW resonator.

2. The BAW resonator of claim 1 wherein the first polarization of the antiparallel part is opposite to the central polarization of the ferroelectric central portion, while the second polarization of the parallel part is the same as the central polarization of the ferroelectric central portion.

3. The BAW resonator of claim 2 wherein the first polarization of the antiparallel part and the second polarization of the parallel part substantially cancel each other out, such that the combined polarization of the ferroelectric BO portion is a zero polarization.

4. The BAW resonator of claim 2 wherein:
the antiparallel part includes a plurality of antiparallel rings;
the parallel part includes a plurality of parallel rings alternating with the plurality of antiparallel rings in a horizontal plane;
each of the plurality of antiparallel rings has a closed ring shape in the horizontal plane, extends vertically through the ferroelectric BO portion, and has the first polarization; and
each of the plurality of parallel rings has a closed ring shape in the horizontal plane, extends vertically through the ferroelectric BO portion, and has the second polarization.

5. The BAW resonator of claim 4 wherein:
the plurality of antiparallel rings is not equally spaced; and
the plurality of antiparallel rings has a lower density adjacent to an interior side of the ferroelectric BO portion and a higher density adjacent to an outer edge of the ferroelectric BO portion, such that the combined polarization of the ferroelectric BO portion reduces from the interior side of the ferroelectric BO portion towards the outer edge of the ferroelectric BO portion.

6. The BAW resonator of claim 4 wherein the plurality of antiparallel rings is equally spaced.

7. The BAW resonator of claim 2 wherein:
the antiparallel part includes a plurality of antiparallel bars, and the parallel part includes a plurality of parallel bars alternating with the plurality of antiparallel bars in a horizontal plane;
each of the plurality of antiparallel bars extends through the ferroelectric BO portion in the horizontal plane and vertically through the ferroelectric BO portion, and has the first polarization;
the plurality of antiparallel bars surrounds the ferroelectric central portion and are parallel to each other along periphery sides of the ferroelectric layer;
each of the plurality of parallel bars extends through the ferroelectric BO portion in the horizontal plane and vertically through the ferroelectric BO portion, and has the second polarization; and
the plurality of parallel bars surrounds the ferroelectric central portion and are parallel to each other at each periphery side of the ferroelectric layer.

8. The BAW resonator of claim 2 wherein:
the antiparallel part includes a plurality of discrete antiparallel posts dispersed at the periphery of the ferroelectric layer and confined in the ferroelectric BO portion;
each of the plurality of discrete antiparallel posts is separated from each other by the parallel part; and
each of the plurality of discrete antiparallel posts extends vertically through the ferroelectric BO portion and has the first polarization.

9. The BAW resonator of claim 8 wherein the plurality of discrete antiparallel posts is equally spaced.

10. The BAW resonator of claim 8 wherein the plurality of discrete antiparallel posts is unequally spaced.

11. The BAW resonator of claim 8 wherein each of the plurality of discrete antiparallel posts has a same shape and a same size in the horizontal plane.

12. The BAW resonator of claim 8 wherein the plurality of discrete antiparallel posts has more than one shape in the horizontal plane.

13. The BAW resonator of claim 8 wherein the plurality of discrete antiparallel posts has more than one size in the horizontal plane.

14. The BAW resonator of claim 1 wherein the top electrode structure comprises a top electrode base over the ferroelectric layer and a BO ring protruding from a periphery of the top electrode base, wherein:
a region of the BAW resonator, within which the BO ring is located is a BO region; and
the ferroelectric BO portion is confined within the BO region and aligned underneath the BO ring, while the ferroelectric central portion is not covered by the BO ring.

15. The BAW resonator of claim 1 wherein the top electrode structure has a flat shape.

16. The BAW resonator of claim 1 wherein the ferroelectric material is scandium aluminum nitride (ScₓAl₁₋ₓN) and the P-E curve of ScₓAl₁₋ₓN is dependent on a scandium concentration x.

17. The BAW resonator of claim 1 further comprises a bottom Brag reflector formed underneath the bottom electrode.

18. The BAW resonator of claim 17 further comprises a top Brag reflector formed over the top electrode structure.

19. A method of implementing a bulk acoustic wave (BAW) resonator, comprising:
providing an initial resonator precursor, which includes a bottom electrode and an initial ferroelectric layer over the bottom electrode, wherein the initial ferroelectric layer is formed of a ferroelectric material, which has a box-shape polarization-electric field (P-E) curve;
providing a patterned bias electrode structure on a periphery of a top surface of the initial ferroelectric layer, wherein:
a region of the initial resonator precursor, within which the patterned bias electrode structure is located is a border (BO) region;
the initial ferroelectric layer has an initial polarization, and includes an initial ferroelectric BO portion, which is confined within the BO region, and a ferroelectric central portion, which is surrounded by the initial ferroelectric BO portion and not covered by the patterned bias electrode structure; and
the initial ferroelectric BO portion includes a first part, which is aligned and underneath the patterned bias electrode structure, and a second part, which is not covered by the patterned bias electrode structure; and
applying a direct current (DC) bias voltage between the patterned bias electrode structure and the bottom electrode to convert the initial ferroelectric layer to a ferroelectric layer, which includes a ferroelectric BO portion converted from the initial ferroelectric BO portion and the ferroelectric central portion surrounded by the ferroelectric BO portion, wherein:
the ferroelectric central portion remains the initial polarization and is configured to provide a resonance of the BAW resonator;
the first part of the initial ferroelectric BO portion is converted to an antiparallel part with a first polarization within the ferroelectric BO portion, while the second part of the initial ferroelectric BO portion remains the initial polarization and forms a parallel part within the ferroelectric BO portion; and
the DC bias voltage is selected, such that an electric field between the patterned bias electrode structure and the bottom electrode results in the first polarization of the antiparallel part being opposite the initial polarization, wherein the first polarization of the antiparallel part and the initial polarization of the parallel part at least partially cancel each other out, such that an absolute value of a combined polarization of the ferroelectric BO portion is smaller than an absolute value of the initial polarization of the ferroelectric central portion.

20. The method of claim 19 further comprising:
removing the DC bias voltage;
removing the patterned bias electrode structure; and
providing a top electrode structure over a top surface of the ferroelectric layer.

21. The method of claim 20 wherein the top electrode structure comprises a top electrode base over the ferroelectric layer and a BO ring protruding from a periphery of the top electrode base, wherein the BO ring is confined in the BO region and the ferroelectric central portion is not covered by the BO ring.

22. The method of claim 20 wherein the top electrode structure has a flat shape.

23. The method of claim 20 wherein after the DC bias voltage is removed, the absolute value of the combined polarization of the ferroelectric BO portion is constant.

24. The method of claim 23 wherein the combined polarization of the ferroelectric BO portion is a zero polarization.

25. The method of claim 19 wherein the ferroelectric material is scandium aluminum nitride (ScₓAl₁₋ₓN) and the P-E curve of ScₓAl₁₋ₓN is dependent on a scandium concentration x.

26. The method of claim 19 wherein:
the patterned bias electrode structure includes a plurality of electrode rings with a gap between adjacent ones of the plurality of electrode rings; and
each of the plurality of electrode rings has a closed ring shape in the horizontal plane.

27. The method of claim 26 wherein:
the plurality of electrode rings is not equally spaced; and
the plurality of electrode rings has a lower density adjacent to an interior side of the initial ferroelectric BO portion and a higher density adjacent to an outer edge of the initial ferroelectric BO portion.

28. The method of claim 19 wherein:
the patterned bias electrode structure includes a plurality of discrete electrode elements, each of which has a shape of a group consisting of bars, rectangles, squares, circles, and ovals in the horizontal plane; and
the plurality of electrode elements surrounds the ferroelectric central portion and are parallel to each other at each side of the periphery of the top surface of the initial ferroelectric layer.

29. A system, comprising:
radio-frequency (RF) input circuitry;
RF output circuitry; and
filter circuitry, which includes at least one bulk acoustic wave (BAW) resonator, connected between the RF input circuitry and the RF output circuitry, wherein the at least one BAW resonator comprises:
a bottom electrode;
a top electrode structure; and
a ferroelectric layer vertically sandwiched between the bottom electrode and the top electrode structure, wherein:
the ferroelectric layer is formed of a ferroelectric material, which has a box-shape polarization-electric field (P-E) curve;
the ferroelectric layer includes a ferroelectric border (BO) portion positioned at a periphery of the ferroelectric layer and a ferroelectric central portion surrounded by the ferroelectric BO portion;
the ferroelectric BO portion includes an antiparallel part with a first polarization and a parallel part with a second polarization, which is in an opposite direction of the first polarization, wherein the first polarization of the antiparallel part and the second polarization of the parallel part at least partially cancel each other out, such that an absolute value of a combined polarization of the ferroelectric BO portion is smaller than an absolute value of a central polarization of the ferroelectric central portion; and
the ferroelectric central portion is configured to provide a resonance of the BAW resonator.
